(19) United States
(12) Patent Application Publication
(10) Pub. No.: US 2024/0012498 A1
(43) Pub. Date: Jan. 11, 2024

(54) A COMPUTER MOUSE AND A METHOD FOR PROVIDING A VENTILATION TO A COMPUTER MOUSE

(71) Applicant: DANBERT OY, Espoo (FI)

(72) Inventor: Jonna LÖFLUND, Espoo (FI)

(21) Appl. No.: 18/253,785

(22) PCT Filed: Nov. 22, 2021
(86) PCT No.: PCT/FI2021/050799

§ 371 Date: May 21, 2023

(30) Foreign Application Priority Data
Nov. 23, 2020 (FI) 20206186

(51) Int. Cl. G06F 3/039; G06F 3/0354; H05K 7/20

(52) U.S. Cl. CPC G06F 3/039; G06F 3/03543; H05K 7/20145

(57) ABSTRACT

A computer mouse includes one or more inflow openings arranged to pass an airflow into the computer mouse, one or more outflow openings arranged to pass the airflow out of the computer mouse into contact with a hand of the computer mouse user and a computer mouse ventilation arrangement including an airflow device arranged to provide the airflow through the computer mouse.

### FIELD OF THE INVENTION

The present invention relates to a computer mouse and more particularly to a computer mouse according to preamble of claim 1. The present invention further relates to a method for providing a ventilation to a computer mouse according to preamble of claim 13.

### BACKGROUND OF THE INVENTION

Computer game players use a computer mouse long periods and thus, hand on the computer mouse begin to emit sweat. Computer mouse users use towels for wiping sweat away hands which is complicate during a game.

It is known to use a fan which are arranged to create an airflow outside the computer mouse. The airflow outside the computer mouse is inefficient because the airflow does not meet the parts of hand which are in contact with the computer mouse and thus, emit sweat.

### BRIEF DESCRIPTION OF THE INVENTION

An object of the present invention is to provide a computer mouse and a method for providing a ventilation to a computer mouse so as to solve or at least alleviate the prior art disadvantages.

The objects of the invention are achieved by a computer mouse which are characterized by what is stated in the independent claim 1. The objects of the invention are achieved by a method for providing a ventilation to a computer mouse which are characterized by what is stated in the independent claim 13.

The preferred embodiments of the invention are disclosed in the dependent claims.

The invention is based on the idea of providing a computer mouse comprises one or more inflow openings arranged to pass an airflow into the computer mouse, one or more outflow openings arranged to pass the airflow A out of the computer mouse into contact with a hand of the computer mouse user, and a computer mouse ventilation arrangement comprising an airflow device arranged to provide the airflow through the computer mouse from the one or more inflow openings to the one or more outflow openings.

In one embodiment of present invention, the computer mouse ventilation arrangement comprises one or more ventilation arrangement mounting elements arranged to mount the computer mouse ventilation arrangement to the computer mouse.

That improves reliability of ventilation of the computer mouse.

In one embodiment of present invention, the airflow device comprises a fan.

That improves reliability of ventilation of the computer mouse.

In one embodiment of present invention, the computer mouse ventilation arrangement comprises a ventilation filter arranged to clean the airflow.

That improves reliability of the computer mouse.

In one embodiment of present invention, the computer mouse comprises a computer mouse covering and the one or more outflow openings arranged to the computer mouse covering.

That provides an airflow through the computer mouse covering.

In another embodiment, the computer mouse comprises a computer mouse covering comprising a computer mouse top wall and the one or more outflow openings arranged to the computer mouse top wall.

That provides an airflow through the computer mouse to a hand of the computer mouse user.

In further embodiment, the computer mouse comprises a computer mouse covering comprising a first computer mouse side wall and the one or more outflow openings arranged to the first computer mouse side wall.

That provides an airflow to a side of the computer mouse.

In another further embodiment, the computer mouse comprises a controlling portion, and the one or more outflow openings arranged to the controlling portion. That provides an airflow to a part of hand which sweats most.

On other words, the controlling portion is a part of the computer mouse on which the computer mouse user has fingers when using the computer mouse for controlling a computer and the fingers are a part of hand which sweats most.

In a yet further embodiment, the computer mouse comprises one or more controllers, and the one or more outflow openings arranged through the one or more controllers.

That provides an airflow to a part of hand which sweats.

In a still further embodiment, the computer mouse comprises a computer mouse covering and one or more controllers and the one or more outflow openings arranged between the computer mouse covering and the one or more controllers.

That provides an airflow to a part of hand which sweats.

In one embodiment of present invention, the computer mouse comprises a computer mouse covering and the one or more inflow openings arranged to the computer mouse covering.

That provides an airflow through the computer mouse covering.

In another embodiment, the computer mouse comprises a computer mouse covering comprising a computer mouse bottom wall and one or more inflow openings arranged to the computer mouse bottom wall.

That provides one or more inflow openings such that the one or more inflow openings are convenient for the computer mouse user.

In a further another embodiment, the computer mouse comprises a computer mouse covering comprising a computer mouse back wall and one or more inflow openings arranged to the computer mouse back wall.

That provides one or more inflow openings such that the one or more inflow openings are convenient for the computer mouse user.

In a yet further another embodiment, the computer mouse comprises a computer mouse covering comprising a computer mouse front wall comprising one or more inflow openings and one or more inflow openings arranged to the computer mouse front wall.

That provides one or more inflow openings such that the one or more inflow openings are convenient for the computer mouse user.

In a still another further embodiment, the computer mouse comprises a first computer mouse side wall and one or more inflow openings arranged to the first computer mouse side wall.

That provides one or more inflow openings such that the one or more inflow openings are convenient for the computer mouse user.

In one embodiment of present invention, the computer mouse ventilation arrangement comprises an inflow duct extending between the airflow device and the one or more inflow openings.

That improves inflow to the computer mouse ventilation arrangement.

In one embodiment of present invention, the computer mouse ventilation arrangement comprises a first outflow duct arranged to extend between the airflow device and the one or more outflow openings.

That increases a volume of an outflow.

In another embodiment, the computer mouse ventilation arrangement comprises a first outflow duct and a second airflow duct arranged to extend between the airflow device and the one or more outflow openings.

That increases a volume of an outflow.

In a further another embodiment, the computer mouse ventilation arrangement comprises a ventilation guide arranged to direct the airflow inside the computer mouse.

That increases a volume of an outflow.

In a yet further another embodiment the computer mouse ventilation arrangement comprises a ventilation chamber arranged to direct the airflow towards the one or more outflow openings.

That increases a volume of an outflow.

In one embodiment of present invention, the computer mouse ventilation arrangement comprises a ventilation arrangement cable arranged to supply electrical energy to the mouse ventilation arrangement from a connecting cable between a computer and the computer mouse.

That provides reliable power to the computer mouse ventilation arrangement.

In another embodiment, the computer mouse ventilation arrangement comprises a ventilation arrangement cable arranged to supply electrical energy to the mouse ventilation arrangement from a computer mouse power source.

That provides reliable power to the computer mouse ventilation arrangement.

In a further another embodiment, the computer mouse ventilation arrangement comprises a ventilation arrangement power source arranged to supply electrical energy to the airflow device.

That provides reliable power to the computer mouse ventilation arrangement.

In one embodiment of present invention, the computer mouse ventilation arrangement comprises an airflow controller arranged to adjust the volume of the airflow.

That provides an airflow adjusted according to a need of the computer mouse user.

In another embodiment, the computer mouse ventilation arrangement comprises an airflow controller arranged to enable the computer mouse user to adjust from outside of the computer mouse the volume of the airflow.

That provides an easy way to adjust the airflow.

In one embodiment of present invention, the computer mouse ventilation arrangement comprises a ventilation arrangement power switch arranged to turn on and off the mouse ventilation arrangement.

That provides an airflow according to need of the computer mouse user.

In another embodiment, the computer mouse ventilation arrangement comprises a ventilation arrangement power switch arranged to enable the computer mouse user from outside of the computer mouse to turn on and off the mouse ventilation arrangement.

That provides an easy way to turn the airflow device on and off.

In one embodiment of present invention, the computer mouse comprises a computer mouse covering, and the computer mouse ventilation arrangement is arranged inside the computer mouse covering.

That improves reliability of ventilation of the computer mouse.

The present invention further relates to a method for providing a ventilation to a computer mouse. The method being carried out with a computer mouse comprising a computer mouse ventilation arrangement, one or more inflow openings and one or more outflow openings. The method comprises providing the airflow inside the computer mouse with the computer mouse ventilation arrangement, passing the airflow into the computer mouse through one or more inflow openings, an passing the airflow out of the computer mouse through one or more outflow openings for providing a discharged airflow.

In one embodiment of present invention, the method comprises drying a hand of the computer mouse user with the discharged airflow.

That reduces sweat on the hands of the computer mouse user.

In one embodiment, the method being carried out with any above disclosed embodiment of a computer mouse.

An advantage of the invention is that an airflow through the computer mouse dries a hand of a computer mouse user. Especially, the airflow through the computer mouse dries parts of the hand which the computer mouse user uses to operate the computer mouse. Further, the computer mouse user may adjust the airflow according to need for drying. Furthermore, the filter prevents dust entering inside the mouse.

### BRIEF DESCRIPTION OF THE DRAWINGS

The invention is described in detail by means of specific embodiments with reference to the enclosed drawings, in which

FIG. 1a shows schematically a computer mouse ventilation arrangement according to one embodiment of the present invention as seen from one side;

FIG. 1b shows schematically the computer mouse ventilation arrangement shown in FIG. 1a as seen from different side;

FIG. 2 shows schematically a computer mouse ventilation arrangement according to another embodiment of the present invention;

FIG. 3 shows schematically a computer mouse ventilation arrangement according to still another embodiment of the present invention;

FIG. 4 shows schematically still another embodiment of a computer mouse ventilation arrangement according to the invention;

FIG. 5 shows schematically still another embodiment of a computer mouse ventilation arrangement according to the invention as seen from one side;

FIG. 6a shows schematically still another embodiment of a computer mouse ventilation arrangement according to the invention as seen from one side;

FIG. 6b shows schematically the computer mouse ventilation arrangement shown in FIG. 6a as seen from different side;

FIG. 7 shows schematically still another embodiment of a computer mouse ventilation arrangement according to the invention; and

FIGS. 8-14 shows schematically embodiments of a computer mouse according to the invention.

### DETAILED DESCRIPTION OF THE INVENTION

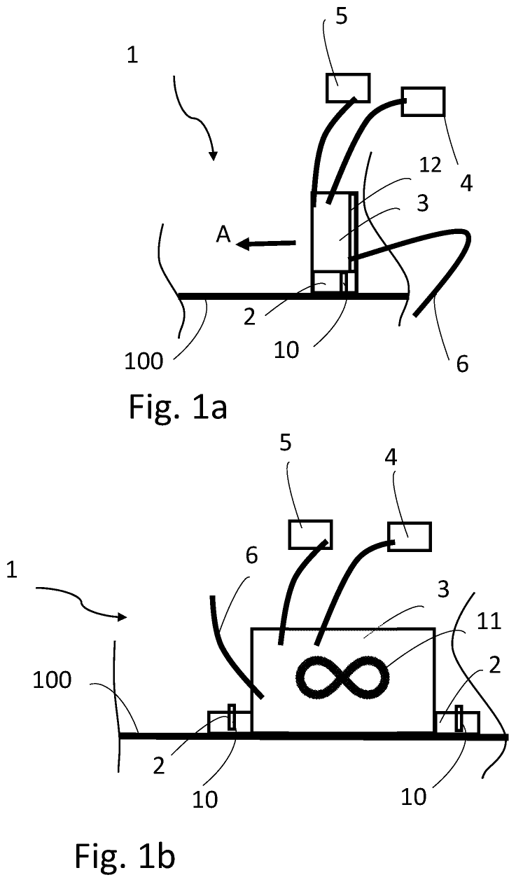

FIGS. 1a and 1b show schematically a computer mouse ventilation arrangement 1 according to one embodiment of the present invention. The computer mouse ventilation arrangement 1 comprises an airflow device 3 arranged to provide an airflow A through a computer mouse 100 into contact with the hand of the computer mouse 100 user. In other words, the airflow A is arranged to dry a hand of a computer mouse 100 user.

In one embodiment, the airflow device 3 comprises a fan 11. The fan 11 is arranged to provide the airflow A.

In one preferred embodiment, the fan 11 is arranged to operate with 5 voltage.

In one embodiment, the computer mouse ventilation arrangement 1 comprises a ventilation filter 14 arranged to clean the airflow A.

In one embodiment the ventilation filter 14 is arranged to clean the airflow A before the airflow A enters inside the computer mouse 100.

Typically, the ventilation filter 14 is arranged to remove dust and other small particles from the airflow A.

In one embodiment, the ventilation filter 14 is arranged to be removable.

Thus, the computer mouse 100 user may clean or replace the ventilation filter 14.

In one embodiment, the computer mouse ventilation arrangement 1 comprises a ventilation arrangement cable 6 arranged to supply electrical energy to the mouse ventilation arrangement 1.

In one embodiment, the computer mouse ventilation arrangement 1 comprises one or more ventilation mounting elements 2 arranged to mount the mouse ventilation arrangement 1 to the computer mouse 100.

In one embodiment, the one or more ventilation mounting elements 2 comprises one or more mounting connector 10.

In one embodiment the one or more mounting connector 10 comprises a screw.

In one embodiment, the one or more mounting connector 10 comprises a snap-fit connector.

In one embodiment, the computer mouse ventilation arrangement 1 comprises a ventilation arrangement power switch 4 arranged to turn on and off the mouse ventilation arrangement 1.

In one embodiment, the computer mouse ventilation arrangement 1 comprises an airflow controller 5 arranged to adjust a volume of the airflow A.

In one embodiment, the airflow controller 5 is arranged to adjust a speed of the fan 11.

It should be noted that a one or more ventilation mounting elements 2 may mount the mouse ventilation arrangement 1 to a computer mouse 100 or to any part or parts which are fixed to the computer mouse 100.

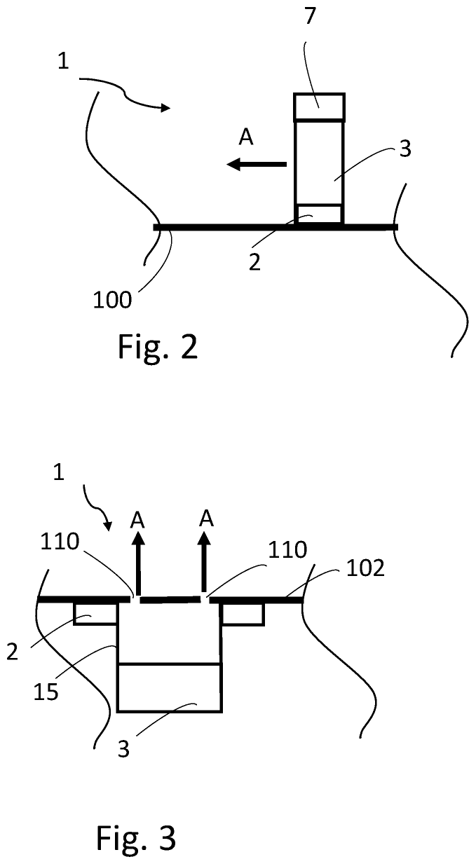

FIG. 2 shows schematically a computer mouse ventilation arrangement according to one embodiment of the present invention in which the computer mouse ventilation arrangement 1 comprises a ventilation arrangement power source 7 arranged to supply electrical energy to the airflow device 3.

In one embodiment the ventilation arrangement power source 7 comprises a battery.

In one embodiment the ventilation arrangement power source 7 comprises a rechargeable battery.

It should be noted the different embodiments of FIGS. 1a and 1b may combined in any possible suitable manner with the different embodiments of FIG. 2.

FIG. 3 shows schematically a computer mouse ventilation arrangement 1 according to one embodiment of the present invention in which the computer mouse ventilation arrangement 1 comprises a ventilation chamber 15. The computer mouse 100 comprises a computer mouse covering 102 and one or more outflow openings 110 arranged to the computer mouse covering 102. The ventilation chamber 15 is arranged to direct the airflow A towards the one or more outflow openings 110.

The ventilation chamber 15 is arranged to prevent the airflow A spread inside the computer mouse 100.

In one embodiment, the ventilation chamber 15 is arranged to surround the airflow device 3.

In one embodiment, the airflow device 3 is arranged inside the ventilation chamber 15.

In one embodiment, the ventilation chamber 15 is arranged to surround the one or more outflow openings 110.

In one embodiment, the one or more ventilation mounting elements 2 are arranged to mount the ventilation chamber 15 to the computer mouse covering 102 around the one or more outflow openings 110 and the airflow device 3 is fixed to the ventilation chamber 15.

It should be noted the different embodiments of FIGS. 1a-2 may combined in any possible suitable manner with the different embodiments of FIG. 3.

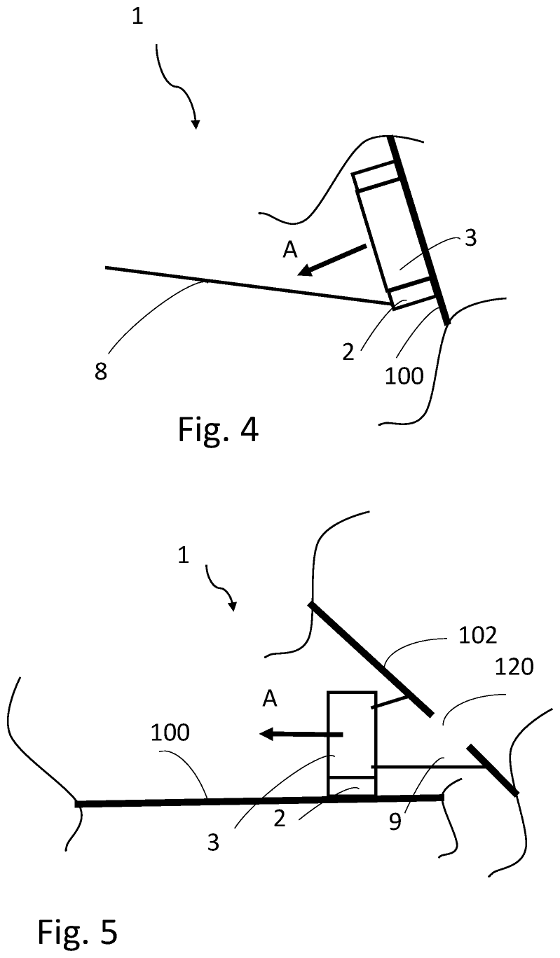

FIG. 4 shows schematically a computer mouse ventilation arrangement 1 according to one embodiment of the present invention in which the computer mouse ventilation arrangement 1 comprises a ventilation guide 8.

The ventilation guide 8 is arranged to direct the airflow A inside the computer mouse 100 and thus, the ventilation guide 8 increases a volume of the airflow A in a desired direction. In other words, the ventilation guide 8 is arranged to change a direction of the airflow A.

In one embodiment, the ventilation guide 8 is arranged to surround the airflow device 3.

In one embodiment, the ventilation guide 8 comprises a wall.

In an alternative embodiment, the ventilation guide 8 comprises a wall having a channel shape.

In one embodiment, the airflow device 3 is arranged inside the ventilation guide 8.

In one embodiment, the ventilation guide 8 is arranged in a transverse direction to the airflow A coming from the airflow device 3 It should be noted the different embodiments of FIGS. 1a-3 may combined in any possible suitable manner with the different embodiments of FIG. 4.

FIG. 5 shows schematically a computer mouse ventilation arrangement 1 according to one embodiment of the present invention in which the computer mouse ventilation arrangement 1 comprises an inflow duct 9 arranged to conduct the airflow A to the airflow device 3.

In other words, the airflow A is arranged to flow via the inflow duct 9 to the airflow device 3.

In one embodiment, the airflow A is arranged to flow via the inflow duct 9 from out of the computer mouse 100 to the airflow device 3.

In one embodiment, the inflow duct 9 comprises a tube arranged to extend between the computer mouse covering 102 and the airflow device 3.

In one embodiment, the inflow duct 9 has a circular cross-section.

In an alternative embodiment, the inflow duct 9 has a rectangular cross-section.

It should be noted the different embodiments of FIGS. 1a-4 may combined in any possible suitable manner with the different embodiments of FIG. 5.

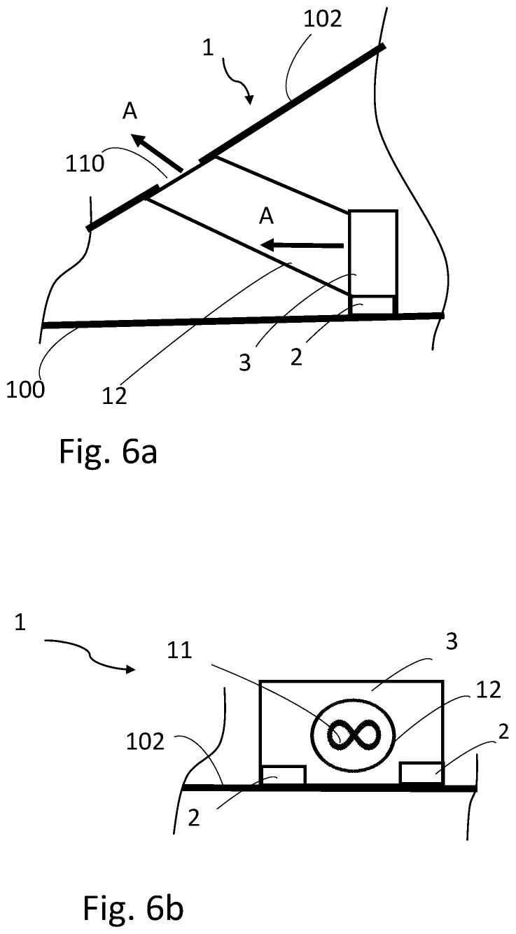

FIGS. 6a and 6b show schematically a computer mouse ventilation arrangement 1 according to one embodiment of the present invention in which the computer mouse ventilation arrangement 1 comprises a first outflow duct 12 arranged to conduct the airflow A from the airflow device 3.

In one embodiment, the airflow A is arranged to flow via the first outflow duct 12 to the one or more outflow openings 110.

In one embodiment, the first outflow duct 12 comprises a tube arranged to extend between the computer mouse covering 102 and the airflow device 3.

In one embodiment, the first outflow duct 12 is arranged to conduct the airflow A into contact with the hand of the computer mouse 100 user.

In one embodiment, the first outflow duct 12 is arranged to conduct the airflow A from the airflow device 3 into contact with a forefinger and a middle finger of the computer mouse 100 user.

In one embodiment, the first outflow duct 12 has a circular cross-section.

In an alternative embodiment, the first outflow duct 12 has a rectangular cross-section.

It should be noted the different embodiments of FIGS. 1a-5 may combined in any possible suitable manner with the different embodiments of FIGS. 6a and 6b.

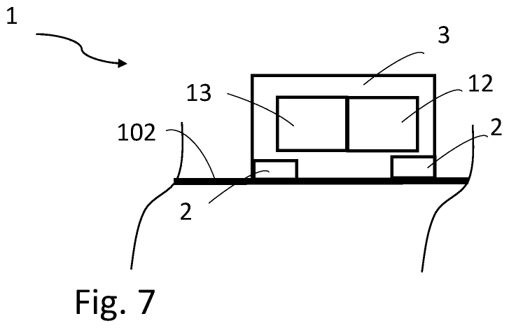

FIG. 7 shows schematically a computer mouse ventilation arrangement 1 according to one embodiment of the present invention in which the computer mouse ventilation arrangement 1 comprises a first outflow duct 12 arranged to conduct the airflow A from the airflow device 3 into contact with one finger of the computer mouse 100 user and a second airflow duct 13 arranged to conduct the airflow A into contact with another finger of the computer mouse 100 user.

In one embodiment, the second airflow duct 13 has a circular cross-section.

In an alternative embodiment, the second airflow duct 13 has a rectangular cross-section.

It should be noted the different embodiments of FIGS. 1a-6b may combined in any possible suitable manner with the different embodiments of FIG. 7.

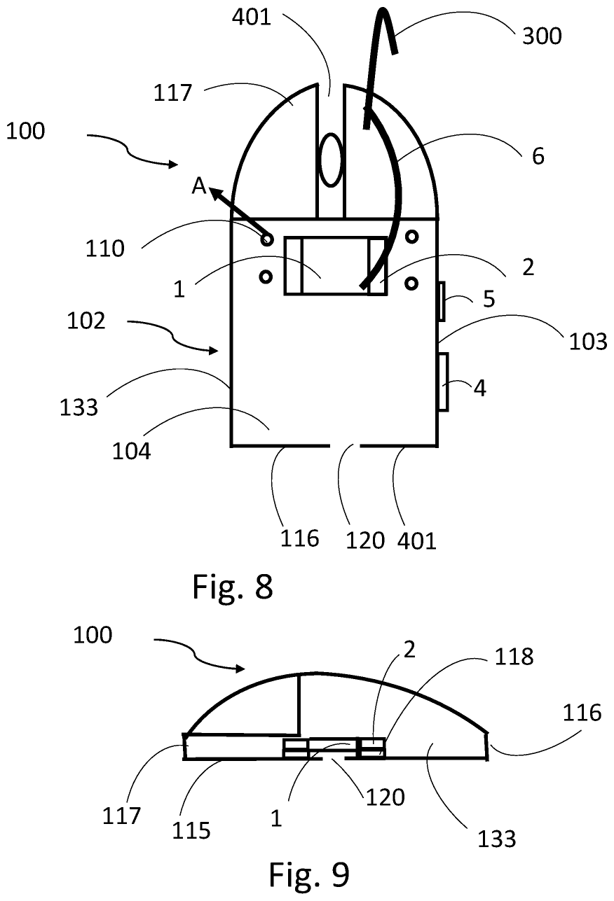

FIG. 8 shows schematically one embodiment of a computer mouse 100 according to the invention in which the computer mouse 100 comprises the computer mouse ventilation arrangement 1 arranged to provide an airflow A through the computer mouse 100 into contact with a hand of the computer mouse 100 user. The mouse ventilation arrangement 1 comprises the airflow device 3 arranged to provide the airflow A.

The airflow A is arranged to dry the hand of the computer mouse 100 user.

The computer mouse 100 further comprises one or more inflow openings 120 arranged to pass the airflow A into the computer mouse 100 and one or more outflow openings 110 arranged to pass the airflow A out of the computer mouse 100.

The computer mouse 100 comprises a computer mouse covering 102.

The computer mouse covering 102 comprises a computer mouse top wall 104 arranged to form a top of the computer mouse 100. The computer mouse top wall 104 is arranged to face upwards when the computer mouse 100 user using the computer mouse 100. Thus, the computer mouse 100 user may put a palm onto the computer mouse top wall 104.

The computer mouse covering 102 comprises a computer mouse bottom wall 115 arranged to form a bottom of the computer mouse 100. The computer mouse bottom wall 115 is arranged to face downwards when the computer mouse 100 user using the computer mouse 100. In other words, the computer mouse 100 user may put the computer mouse bottom wall 115 on a table. The computer mouse bottom wall 115 is shown in FIG. 9.

The computer mouse 100 having a computer mouse front end 400 in front of the computer mouse 100 and a computer mouse back end 401 in back of the computer mouse 100.

In one embodiment, the computer mouse covering 102 comprises a computer mouse front wall 117. The computer mouse front wall 117 extends between the computer mouse top wall 104 and the computer mouse bottom wall 115. The computer mouse front wall 117 is arranged to face forward when the computer mouse 100 user using the computer mouse 100. The computer mouse front wall 117 is arranged to the computer mouse front end 400. In other words, the computer mouse front wall 117 is arranged to face away from the computer mouse 100 user when the computer mouse 100 user using the computer mouse 100.

In one embodiment, the computer mouse covering 102 comprises a computer mouse back wall 116. The computer mouse back wall 116 extends between the computer mouse top wall 104 and the computer mouse bottom wall 115. The computer mouse back wall 116 is arranged to face in an opposite direction to the computer mouse front wall 117. In other words, the computer mouse back wall 118 is arranged to the computer mouse back end 401.

In one embodiment, the computer mouse covering 102 comprises a first computer mouse side wall 103 and a second computer mouse side wall 133. The first computer mouse side wall 103 extends between the computer mouse top wall 104 and the computer mouse bottom wall 115. The second computer mouse side wall 133 extends between the computer mouse top wall 104 and the computer mouse bottom wall 115. The first computer mouse side wall 103 and the second computer mouse side wall 133 are arranged to form sides of the computer mouse covering 102.

In one embodiment the one or more outflow openings 110 are arranged to the computer mouse covering 102.

In one embodiment, the one or more outflow openings 110 are arranged to the computer mouse top wall 104.

In one embodiment, the one or more inflow openings 120 are arranged to the computer mouse covering 102.

In one embodiment, the one or more inflow openings 120 are arranged to the computer mouse back wall 116.

In one embodiment, the computer mouse 100 further comprises a mouse connecting cable 300 between a computer and the computer mouse 100, the computer mouse ventilation arrangement 1 comprises a ventilation arrangement cable 6 arranged to supply electrical energy to the mouse ventilation arrangement 1 from the mouse connecting cable 300.

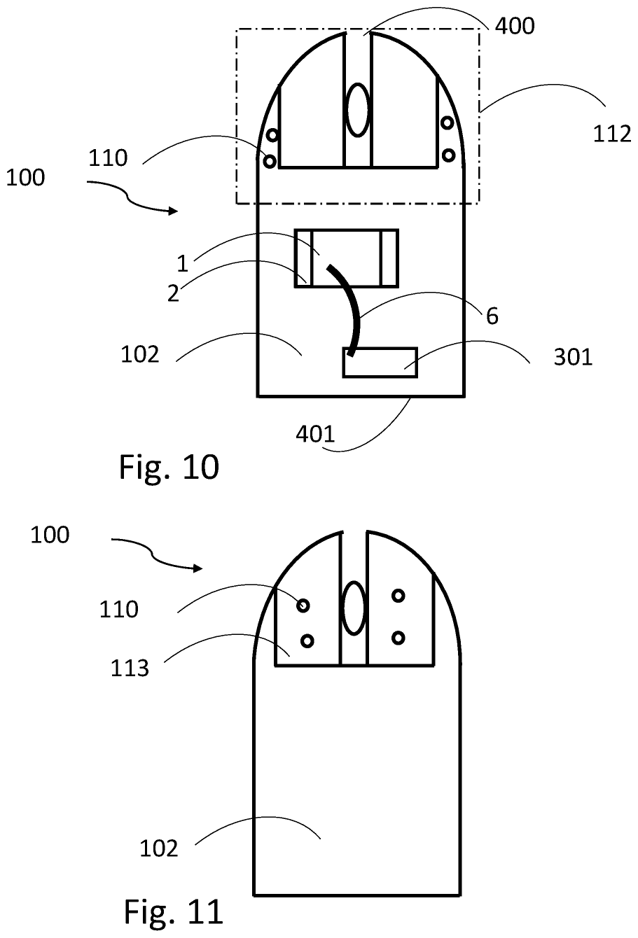

In an alternative embodiment, the computer mouse further comprises a computer mouse power source 301, the computer mouse ventilation arrangement 1 comprises a ventilation arrangement cable 6 arranged to supply electrical energy to the mouse ventilation arrangement 1 from the computer mouse power source 301. The computer mouse power source 301 is shown in FIG. 10.

In a further alternative embodiment, the computer mouse ventilation arrangement 1 comprises a ventilation arrangement power source 7 arranged to supply electrical energy to the airflow device 3. The ventilation arrangement power source 7 is shown in FIG. 2.

In one embodiment, the computer mouse ventilation arrangement 1 comprises an airflow controller 5 arranged to adjust the volume of the airflow A.

In an alternative embodiment, the computer mouse ventilation arrangement 1 comprises an airflow controller 5 arranged to enable the computer mouse 100 user to adjust from outside of the computer mouse 100 the volume of the airflow A.

In one embodiment, a size of the one or more inflow openings 120 is arranged to be adjustable.

In an alternative embodiment, a size of the one or more outflow openings 110 is arranged to be adjustable.

In a further alternative embodiment, a size of the one more inflow openings 120 and a size of the one or more outflow openings 110 are arranged to be adjustable.

In one alternative embodiment, the ventilation arrangement power switch 4 is arranged to enable the computer mouse 100 user from outside of the computer mouse 100 to turn on and off the mouse ventilation arrangement 1.

In one embodiment the ventilation arrangement power switch 4 and the airflow controller 5 are fixed to the computer mouse covering 102.

It should be noted the different embodiments of FIGS. 1a-7 may combined in any possible suitable manner with the different embodiments of FIG. 8.

FIG. 9 shows schematically one embodiment of a computer mouse 100 according to the invention in which the one or more inflow openings 120 are arranged to the computer mouse bottom wall 115 and the computer mouse covering 102 comprises one or more mouse covering mounting elements 118 arranged to receive the one or more ventilation mounting elements 2.

In one embodiment, the computer mouse ventilation arrangement 1 is arranged on the one or more inflow openings 120.

In other words, the computer mouse ventilation arrangement 1 is arranged to suck the airflow directly through the one or more inflow openings 120.

It should be noted the different embodiments of FIGS. 1a-8 may combined in any possible suitable manner with the different embodiments of FIG. 9.

FIG. 10 shows schematically one embodiment of the computer mouse 100 according to the invention in which the computer mouse 100 further comprises a computer mouse power source 30 and the computer mouse ventilation arrangement 1 comprises a ventilation arrangement cable 6 arranged to supply electrical energy to the mouse ventilation arrangement 1 from the computer mouse power source 301.

In one embodiment, the computer mouse 100 comprising a controlling portion 112, and the one or more outflow openings 110 arranged to the controlling portion 112.

The controlling portion 112 is arranged to the computer mouse front end 400.

In other words, the controlling portion 112 is a part of the computer mouse 100 on which the computer mouse 100 user has fingers when using the computer mouse 100 for controlling a computer.

It should be noted the different embodiments of FIGS. 1a-9 may combined in any possible suitable manner with the different embodiments of FIG. 10.

FIG. 11 shows schematically one embodiment of the computer mouse 100 according to the invention in which the computer mouse 100 comprises one or more controllers 113, and the one or more outflow openings 110 arranged through the one or more controllers 113.

The one or more controllers 113 are parts of the computer mouse 100 which the computer mouse 100 user uses for controlling a computer.

It should be noted the different embodiments of FIGS. 1a-10 may combined in any possible suitable manner with the different embodiments of FIG. 11.

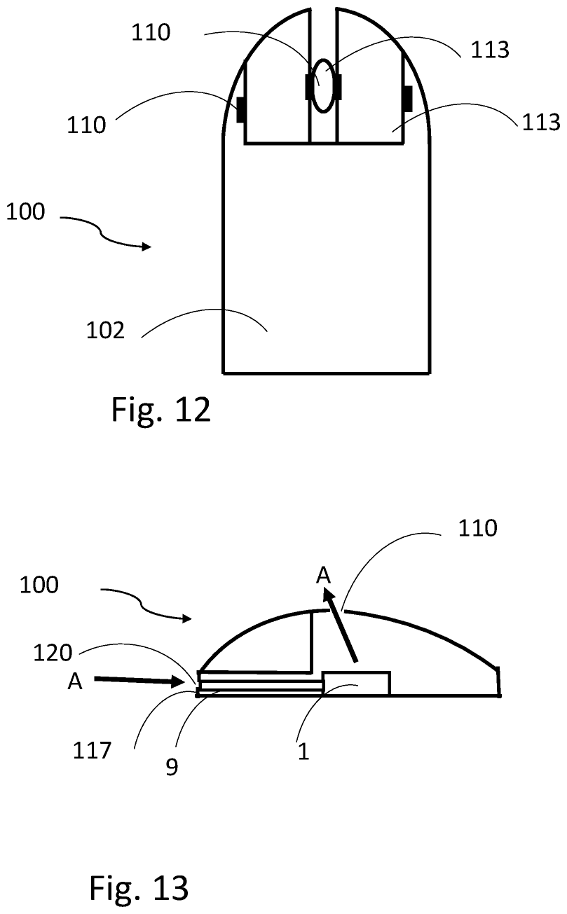

FIG. 12 shows schematically one embodiment of the computer mouse 100 according to the invention in which the computer mouse comprises 100 a computer mouse covering 102 and one or more controllers 113, and the one or more outflow openings 110 arranged between the computer mouse covering 102 and the one or more controllers 113.

It should be noted the different embodiments of FIGS. 1a-11 may combined in any possible suitable manner with the different embodiments of FIG. 12.

FIG. 13 shows schematically one embodiment of the computer mouse 100 according to the invention in which the computer mouse ventilation arrangement 1 comprises an inflow duct 9 extending between the airflow device 3 and the one or more inflow openings 120.

In one embodiment, the computer mouse 100 comprises the one or more inflow openings 120 arranged to the computer mouse front wall 117.

In one embodiment, the computer mouse 100 comprises the one or more inflow openings 120 arranged to the first computer mouse side wall 103.

In one embodiment, the computer mouse 100 comprises the one or more inflow openings 120 arranged the second computer mouse side wall 133

In one embodiment, the inflow duct 9 is arranged to surround the one or more inflow openings 120.

It should be noted the different embodiments of FIGS. 1a-12 may combined in any possible suitable manner with the different embodiments of FIG. 13.

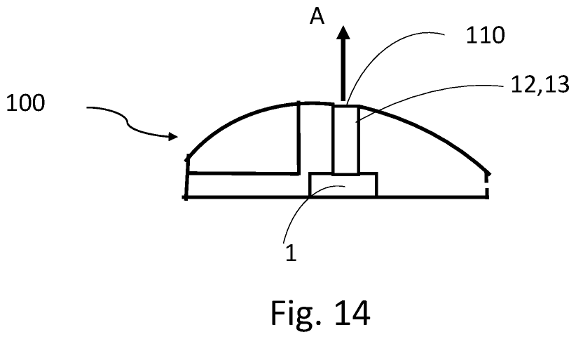

FIG. 14 shows schematically one embodiment of a computer mouse 100 according to the invention in which the computer mouse ventilation arrangement 1 comprises a first outflow duct 12 arranged to extend between the airflow device 3 and the one or more outflow openings 110.

In one embodiment, the computer mouse ventilation arrangement 1 comprises a first outflow duct 12 and a second airflow duct 13 arranged to extend between the airflow device 3 and the one or more outflow openings 110.

In one embodiment, first outflow duct 12 is arranged to surround the one or more outflow openings 110.

In one embodiment, the second outflow duct 13 is arranged to surround the one or more outflow openings 110.

It should be noted the different embodiments of FIGS. 1a-13 may combined in any possible suitable manner with the different embodiments of FIG. 14.

The present invention further provides a method for providing a ventilation to a computer mouse 100. The method being carried out with a computer mouse 100 comprising a computer mouse ventilation arrangement 1, one or more inflow openings 120 and one or more outflow openings 110.

The computer mouse 100 utilized in the method preferably corresponds to above in relation to FIGS. 1a-14 disclosed computer mouse 1.

The method comprises providing the airflow A inside the computer mouse 100 with the computer mouse ventilation arrangement 1, passing the airflow A into the computer mouse 100 through one or more inflow openings 120, and passing the airflow A out of the computer mouse 100 through one or more outflow openings 110 for providing a discharged airflow.

In one embodiment of the method, the method comprises drying a hand of the computer mouse 100 user with the discharged airflow.

In one embodiment of the method, the method comprises cleaning the airflow A with a ventilation filter 14.

The invention has been described above with reference to the examples shown in the figures. However, the invention is in no way restricted to the above examples but may vary within the scope of the claims.

1.-15. (canceled)

16. A computer mouse, wherein the computer mouse comprises:
one or more inflow openings arranged to pass an airflow into the computer mouse;
one or more outflow openings arranged to pass the airflow out of the computer mouse; and
a computer mouse ventilation arrangement comprising an airflow device arranged to provide the airflow through the computer mouse from the one or more inflow openings to the one or more outflow openings.

17. The computer mouse according to claim 16, wherein the computer mouse ventilation arrangement comprises one or more ventilation arrangement mounting elements arranged to mount the computer mouse ventilation arrangement to the computer mouse.

18. The computer mouse according to claim 16, wherein the airflow device comprises a fan.

19. The computer mouse according to claim 16, wherein the computer mouse ventilation arrangement comprises a ventilation filter arranged to clean the airflow.

20. The computer mouse according to claim 16, wherein at least one of:
the computer mouse comprises a computer mouse covering and the one or more outflow openings arranged to the computer mouse covering; or
the computer mouse comprises a computer mouse covering comprising a computer mouse top wall and the one or more outflow openings arranged to the computer mouse top wall; or
the computer mouse comprises a computer mouse covering comprising a first computer mouse side wall and the one or more outflow openings arranged to the first computer mouse side wall; or
the computer mouse comprises a controlling portion, and the one or more outflow openings arranged to the controlling portion; or
the computer mouse comprises one or more controllers, and the one or more outflow openings arranged through the one or more controllers; or
the computer mouse comprises a computer mouse covering and one or more controllers and the one or more outflow openings arranged between the computer mouse covering and the one or more controllers.

21. The computer mouse according to claim 16, wherein at least one of:
the computer mouse comprises a computer mouse covering and the one or more inflow openings arranged to the computer mouse covering; or
the computer mouse comprises a computer mouse covering comprising a computer mouse bottom wall and one or more inflow openings arranged to the computer mouse bottom wall; or
the computer mouse comprises a computer mouse covering comprising a computer mouse back wall and one or more inflow openings arranged to the computer mouse back wall; or
the computer mouse comprises a computer mouse covering comprising a computer mouse front wall comprising one or more inflow openings and one or more inflow openings arranged to the computer mouse front wall; or
the computer mouse comprises a first computer mouse side wall and one or more inflow openings arranged to the first computer mouse side wall.

22. The computer mouse according to claim 16, wherein the computer mouse ventilation arrangement comprises an inflow duct extending between the airflow device and the one or more inflow openings.

23. The computer mouse according to claim 16, wherein at least one of:
the computer mouse ventilation arrangement comprises a first outflow duct arranged to extend between the airflow device and the one or more outflow openings; or
the computer mouse ventilation arrangement comprises a first outflow duct and a second airflow duct arranged to extend between the airflow device and the one or more outflow openings; or
the computer mouse ventilation arrangement comprises a ventilation guide arranged to direct the airflow inside the computer mouse; or
the computer mouse ventilation arrangement comprises a ventilation chamber arranged to direct the airflow towards the one or more outflow openings.

24. The computer mouse according to claim 16, wherein at least one of:
the computer mouse ventilation arrangement comprises a ventilation arrangement cable arranged to supply electrical energy to the mouse ventilation arrangement from a connecting cable between a computer and the computer mouse; or
the computer mouse ventilation arrangement comprises a ventilation arrangement cable arranged to supply electrical energy to the mouse ventilation arrangement from a computer mouse power source; or
the computer mouse ventilation arrangement comprises a ventilation arrangement power source arranged to supply electrical energy to the airflow device.

25. The computer mouse according to claim 16, wherein at least one of:
the computer mouse ventilation arrangement comprises an airflow controller arranged to adjust the volume of the airflow; or
the computer mouse ventilation arrangement comprises an airflow controller arranged to enable the computer mouse user to adjust from outside of the computer mouse the volume of the airflow.

26. The computer mouse according to claim 16, wherein at least one of:
the computer mouse ventilation arrangement comprises a ventilation arrangement power switch arranged to turn on and off the mouse ventilation arrangement; or
the computer mouse ventilation arrangement comprises a ventilation arrangement power switch arranged to enable the computer mouse user from outside of the computer mouse to turn on and off the mouse ventilation arrangement.

27. The computer mouse according to claim 16, wherein:
the computer mouse comprises a computer mouse covering; and
the computer mouse ventilation arrangement is arranged inside the computer mouse covering.

28. A method for providing ventilation to a computer mouse, wherein the computer mouse comprises a computer mouse ventilation arrangement, one or more inflow openings and one or more outflow openings, the method comprising:
providing airflow inside the computer mouse with the computer mouse ventilation arrangement,
passing the airflow into the computer mouse through one or more inflow openings, and
passing the airflow out of the computer mouse through one or more outflow openings for providing a discharged airflow.

29. The method according to claim 28, wherein the method further comprises:
drying a hand of the computer mouse user with the discharged airflow.

30. The method according to claim 28, wherein the method further comprises:
providing the computer mouse with one or more inflow openings arranged to pass an airflow into the computer mouse;
providing the computer mouse with one or more outflow openings arranged to pass the airflow out of the computer mouse; and
providing the computer mouse with a computer mouse ventilation arrangement comprising an airflow device arranged to provide the airflow through the computer mouse from the one or more inflow openings to the one or more outflow openings.

31. The computer mouse according to claim 16, wherein the one or more outflow openings are configured to pass the airflow out of the computer mouse corresponding to a location of a hand of a user of the computer mouse when the computer mouse is in use.

32. The method according to claim 28, further comprising configuring the one or more outflow openings to pass the airflow out of the computer mouse corresponding to a location of a hand of a user of the computer mouse when the computer mouse is in use.
